(19) United States
(12) Patent Application Publication
(10) Pub. No.: US 2023/0184833 A1
(43) Pub. Date: Jun. 15, 2023

(54) INTEGRATED CIRCUIT CHIP HAVING BACK-SURFACE TOPOGRAPHY FOR ENHANCED COOLING DURING CHIP TESTING

(71) Applicant: International Business Machines Corporation, Armonk, NY (US)

(72) Inventor: Mark D. Schultz, Ossining, NY (US)

(21) Appl. No.: 17/550,157

(22) Filed: Dec. 14, 2021

(51) Int. Cl. G01R 31/319; G01R 31/28

(52) U.S. Cl. CPC G01R 31/31905; G01R 31/2877

(57) ABSTRACT

Embodiments of the invention include a method of preparing an integrated circuit (IC) chip to participate in test operations. The method includes accessing a back surface of the IC chip and adding a back-surface topography to the back surface. A surface area of the back-surface topography is greater than a surface area of the back surface.

### BACKGROUND

The present invention relates in general to the fabrication, packaging, and testing of integrated circuits (ICs) formed on chip regions of a semiconductor wafers. More specifically, the present invention relates to fabrication systems, fabrication methods, and resulting structures for IC chips (or IC dies) having a back-surface topography configured and arranged to provide enhanced cooling of the IC chip during chip testing.

Scaling IC chip circuitry to increasingly smaller dimensions impacts the lifetime and reliability of individual chips due to increased fragility, higher power density, more complex devices, and new failure mechanisms. It is known to test the functionality of semiconductor wafers and chips at various fabrication stages including, for failure analysis or other use, after the chip has been completed and packaged. For example, various mechanisms in IC chips cause predictable thermal behavior and/or light emission during operation of the IC chip. Known non-invasive IC chip testing systems use the detection and analysis of such thermal behavior and/or light emissions to detect locations on the IC chip where the thermal behavior and/or light emission behavior indicate an actual or expected failure condition.

An IC chip being tested is often referred to as a device-under-test (DUT). Different IC chip tests require the application of different power levels to the DUT. Accordingly, the DUT will need to tolerate a range of different power levels in order to test the full range of potential failure areas. When the DUT is encapsulated in its final IC packaging, the packing provides various heat dissipation mechanisms. However, because certain types of IC chip testing must be performed without the complete IC packaging in place, some or all of the normal post-packaging heat dissipation mechanisms are not available to a DUT. Accordingly, the previously-described non-invasive IC chip testing systems typically provide some form of heat dissipation mechanism. One type of heat dissipation mechanism is flowing liquid coolant over an exposed back surface of the DUT during testing.

### SUMMARY

Embodiments of the invention include a method of preparing an integrated circuit (IC) chip to participate in test operations. The method includes accessing a back surface of the IC chip and adding a back-surface topography to the back surface. A surface area of the back-surface topography is greater than a surface area of the back surface.

Embodiments of the invention include a method of testing an IC chip. The method includes accessing a back surface of the IC chip and adding a back-surface topography to the back surface. A test regimen is applied to the IC chip while applying power to the IC chip. Cooling fluid is flowed over the back-surface topography to dissipate heat generated as a result of applying power to the IC chip. A surface area of the back-surface topography is greater than a surface area of the back surface.

Embodiments of the invention include an IC chip configured to participate in test operations. The IC chip includes, a front surface and a back surface, wherein the back surface has a back-surface topography. A set of dimensions of the back-surface topography is configured such that a heat dissipation rate through the back-surface topography during the test operations exceeds a heat dissipation rate threshold.

Additional features and advantages are realized through the techniques described herein. Other embodiments and aspects are described in detail herein. For a better understanding, refer to the description and to the drawings.

### BRIEF DESCRIPTION OF THE DRAWINGS

The subject matter which is regarded as the present invention is particularly pointed out and distinctly claimed in the claims at the conclusion of the specification. The foregoing and other features and advantages are apparent from the following detailed description taken in conjunction with the accompanying drawings in which:

FIGS. 1-5 depict the results of fabrication operations for forming an IC chip having a back-surface topography in accordance with embodiments of the invention, in which:

FIG. 1 depicts top-down and cross-sectional views of an IC chip after fabrication operations in accordance with embodiments of the invention;

FIG. 2 depicts top-down and cross-sectional views of an IC chip after fabrication operations in accordance with embodiments of the invention;

FIG. 3 depicts top-down and cross-sectional views of an IC chip after fabrication operations in accordance with embodiments of the invention;

FIG. 4 depicts a cross-sectional views of an IC chip after fabrication operations in accordance with embodiments of the invention; and

FIG. 5 depicts a cross-sectional view of an IC chip after fabrication operations in accordance with embodiments of the invention;

FIG. 6 depicts a test system configured to test an IC chip in accordance with embodiments of the invention;

FIG. 7 depicts a cross-sectional view of an IC chip in accordance with embodiments of the invention;

FIG. 8 depicts a cross-sectional view of an IC chip in accordance with embodiments of the invention;

FIG. 9 depicts a top-down view of an IC chip in accordance with embodiments of the invention;

FIG. 10 depicts a top-down view of an IC chip in accordance with embodiments of the invention;

FIG. 11 depicts a flow diagram illustrating a methodology according to embodiments of the invention;

FIG. 12 depicts semiconductor fabrication systems capable of implementing embodiments of the invention;

FIG. 13 depicts a machine learning system that can be utilized to implement aspects of the invention;

FIG. 14 depicts a learning phase that can be implemented by the machine learning system shown in FIG. 13; and

FIG. 15 depicts details of an exemplary computing system configured to implement various aspects of the invention.

In the accompanying figures and following detailed description of the disclosed embodiments, the various elements illustrated in the figures are provided with three or four digit reference numbers.

### DETAILED DESCRIPTION

For the sake of brevity, conventional techniques related to IC chip fabrication may or may not be described in detail herein. Moreover, the various tasks and process steps described herein can be incorporated into a more comprehensive procedure or process having additional steps or functionality not described in detail herein. In particular, various steps in the fabrication of semiconductor devices and semiconductor-based ICs are well known and so, in the interest of brevity, many conventional steps will only be mentioned briefly herein or will be omitted entirely without providing the well-known process details.

Similarly, conventional techniques related to making and using aspects of the invention may or may not be described in detail herein. In particular, various aspects of computing systems (or processors, or processor systems) and specific computer programs to implement the various technical features described herein are well known. Accordingly, in the interest of brevity, many conventional implementation details are only mentioned briefly herein or are omitted entirely without providing the well-known system and/or process details.

Turning now to an overview of aspects of the present invention, embodiments of the invention provide fabrication systems, fabrication methods, and resulting structures for IC chips (or IC dies) having a back-surface topography designed to provide enhanced cooling of the IC chip during chip testing. In some embodiments of the invention, the chip testing can occur for a portion of production, for example, during chip bring-up, failure analysis, and the like. In some embodiment of the invention, the chip testing can occur for essentially all the chips that are run through a full manufacturing process. In this detailed description, the terms “topography,” “designed topography,” and variations thereof are used to describe a surface on which there are local deviations from a substantially planar surface. Such local deviations do not include “surface roughness” because even in instances where a surface has been processed for smoothness (e.g., through CMP) there will be post-processing surface roughness and unintended surface defects due to machining and other process limitations. Such local deviations also do not include unintended surface defects that can result, for example from ineffective planarization processes, debris from etch operations, and the like. Thus, the terms “substantially planar surface” are used herein to describe a surface that can include post-processing surface roughness and unintended surface defects due to machining and other process limitations.

In accordance with embodiments of the invention, chip testing is performed in a chip testing system that dissipates heat by flowing coolant over the specially designed back-surface topography of the IC-chip. In accordance with aspects of the invention, the back-surface topography is designed to provide enhanced heat dissipation over a planar or substantially planar back-surface by increasing the surface area of the back portion of the IC chip over which the coolant flows. In some embodiments of the invention, the specially designed back-surface topography is formed by exposing a planar or substantially planar back surface of the IC chip, forming a patterned hardmask over the back surface, and applying a time-controlled etching operation (e.g., a reactive ion etch (RIE)) through the patterned hardmask and onto the back surface to form the specially designed back-surface topography having a desired depth. In accordance with aspects of the invention, the hardmask pattern (size, shape, location) and the duration of the time-controlled etch operation are selected such that a surface area of the specially designed back-surface topography is greater than a surface area of the back surface alone (i.e., without the specially designed back-surface topography). In accordance with aspects of the invention, the hardmask pattern and the duration of the etch operation are selected such that a surface area of the specially designed back-surface topography exceeds a surface area of the back surface alone (i.e., without the specially designed back-surface topography) by a predetermined amount. For example, the hardmask pattern and the duration of the time-controlled etch operation can be selected such that a surface area of the specially designed back-surface topography is double a surface area of the back surface alone (i.e., without the specially designed back-surface topography). In some embodiments of the invention, the back surface alone (i.e., without the specially designed back-surface topography) is planar or substantially planar. In embodiments of the invention, a computing system (or processor system) having computer-aided mask design tools, computational fluid dynamics tools, and machine learning tools is configured to perform a computer-implemented method that generates masks and etch duration parameters that are used to form the above-described specially designed back-surface topography. In some embodiments of the invention, the specially designed back-surface topography includes alternating instances of a channel region (or trench region) and a fin-shaped region. In some embodiments of the invention, the chip testing system can be a picosecond imaging circuit analysis (PICA) test system and/or a thermal infrared imaging system.

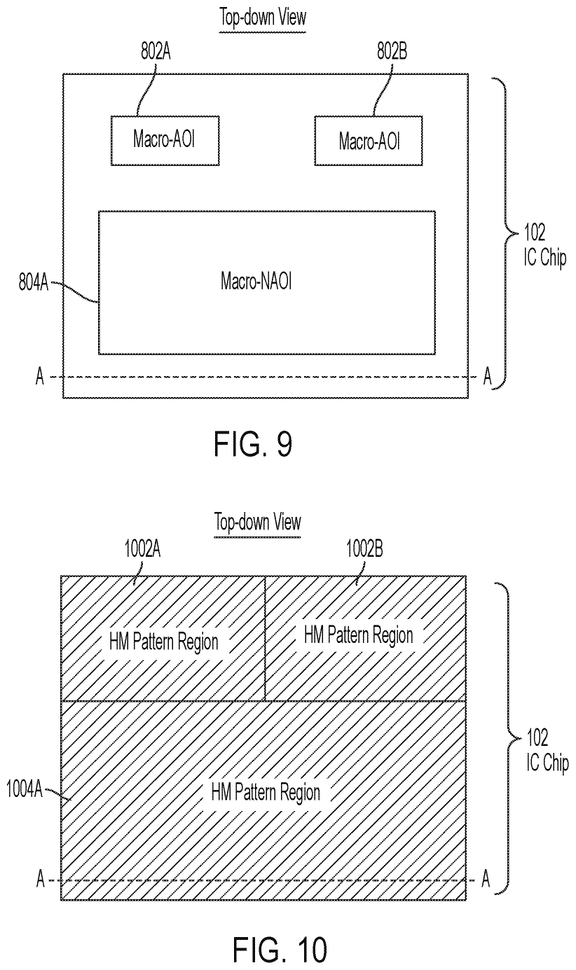

In embodiments of the invention, the specially designed back-surface topography can under some circumstances include lower visibility regions that interfere with light emission visibility of the chip testing system, along with higher visibility regions that do not interfere with light emission visibility of the chip testing system. In accordance with aspects of the invention, portions of the IC chip that are expected to produce useful test data are identified herein as an area-of-interest (AOI), and portions of the IC chip that are not expected to produce useful test data are identified herein as a non-area-of-interest (NAOI). In embodiment of the invention, AOI and NAOI can be determined at a micro-level or a macro-level. Examples of AOI and NAOI determined at a micro-level are micro-AOI 802 and micro-NAOI 804 depicted in FIG. 8. Examples of AOI and NAOI determined at the macro-level are macro-AOI 802A, macro-AOI 802B, and macro-NAOI 804A, which are depicted in FIG. 9.

In accordance with aspects of the invention, the computing system having computer-aided mask design tools, computational fluid dynamics tools, and machine learning tools is configured to perform a computer-implemented method that improves an ability of the chip testing system to detect light emissions by determining the size, shape, and location of the specially designed back-surface topology such that its lower visibility regions are over micro-AOI and such that its higher visibility regions over micro-NAOI. In embodiments of the invention, the computer-implemented method also improves an ability of the chip testing system to dissipate heat during testing by segmenting the specially designed back-surface topography into regions, and designing a back-surface topology region that will be placed over a macro-NAOI to maximize heat dissipation without concern for visibility and without interfering with operation of the IC chip during testing.

In accordance with aspects of the invention, the above-described computer-implemented method can incorporate constraints when determining the size, location, shape, depth, etc. of the specially designed back-surface topography; and/or when segmenting the specially designed back-surface topography into segments or regions. For example, the constraints can set a maximum number of specially designed back-surface segments (e.g., no more than 3). Additional constraints (e.g., coolant flow rates; coolant pressure rates; the specially designed back-surface topography cannot interfere with the performance of the IC chip; and the like) can be applied to the computer-implemented method of determining the size, location, shape, depth, etc. of the specially designed back-surface topography; and/or the computer-implemented method of segmenting the specially designed back-surface topography.

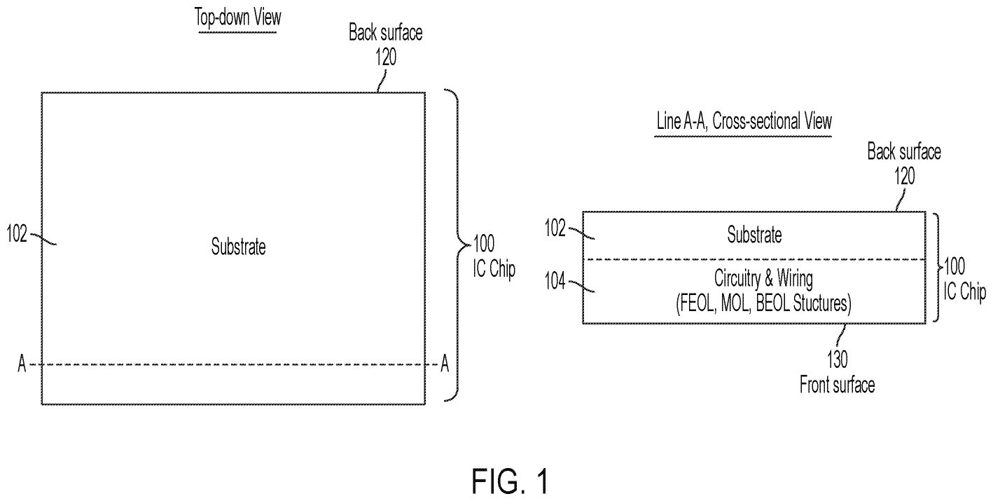

FIGS. 1-5 depict the results of fabrication operations for forming an IC chip 100 having a back-surface topography 502 (shown in FIG. 5) in accordance with embodiments of the invention. In embodiments of the invention, the back-surface topography 502 includes a surface on which there are local deviations from a substantially flat plane. Turning first to FIG. 1, a simplified top-down of the IC chip 100 is shown, along with a cross-sectional view of the IC chip 100 taken along line A-A of the top-down view after fabrication operations in accordance with embodiments of the invention. At this fabrication stage, the layers of the IC chip 100 have been completed, and the IC chip 100 has been singulated (or separated) from a wafer (not shown). In some embodiments of the invention, the IC chip 100 has been assembled into a finished IC package (not shown) that is physically ready for use in customer applications. In embodiments of the invention where the IC chip 100 has been packaged, the package lid and any intervening materials (e.g., thermal interface material) are removed to expose a back surface 120 of the IC chip 100 for application of the fabrication operations shown in FIG. 1-5.

As best shown in the line A-A, cross-sectional view of FIG. 1, the IC chip 100 has been flipped such that its back surface 120 is over its front surface 110. The IC chip 100 includes a substrate 102 and a circuitry & wiring region 104. The substrate 102 can be made of any suitable substrate material, such as, for example, monocrystalline Si, silicon germanium (SiGe), III-V compound semiconductor, II-VI compound semiconductor, or semiconductor-on-insulator (SOI).

The circuitry & wiring region 104 includes front-end-of-line (FEOL), middle-of-line (MOL), and back-end-of-line (BEOL) structures (not shown separately) formed in FEOL, MOL, and BEOL regions (not shown separately) of circuitry & wiring region 104. In general, semiconductor wafers are fabricated in a series of stages, including a FEOL stage, a MOL stage, and a BEOL stage. The process flows for fabricating modern semiconductor wafers are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The FEOL stage processes also involve the formation of a plurality of IC chips or semiconductor die on the surface of a semiconductor wafer. Each IC chip contains circuits formed by electrically connecting active and passive components. The MOL stage typically includes process flows for forming interconnect structures (e.g., lines, wires, metal-filled vias, contacts, and the like) that communicatively couple to active regions (e.g., gate, source, and drain) of the device element. During the BEOL stage, layers of interconnect structures are formed above these logical and functional layers to complete the semiconductor wafer. Most semiconductor wafers need more than one layer of interconnects to form all the necessary connections, and as many as 5-12 layers are added in the BEOL process.

BEOL processes can also include singulating (or removing) individual IC chips from the finished semiconductor wafer and packaging the IC chip(s) to provide structural support and environmental isolation. Referring more specifically to IC chip 100, as previously noted, in embodiments of the invention where the IC chip 100 has been packaged, the package lid and any intervening materials (e.g., thermal interface material) are removed to expose a back surface 120 of the IC chip 100 so that the fabrication operations shown in FIG. 1-5 can be performed.

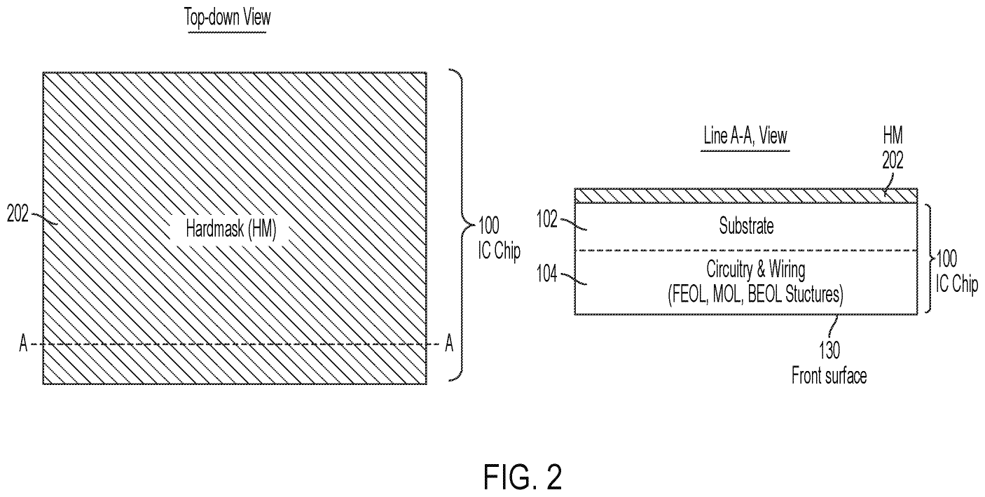

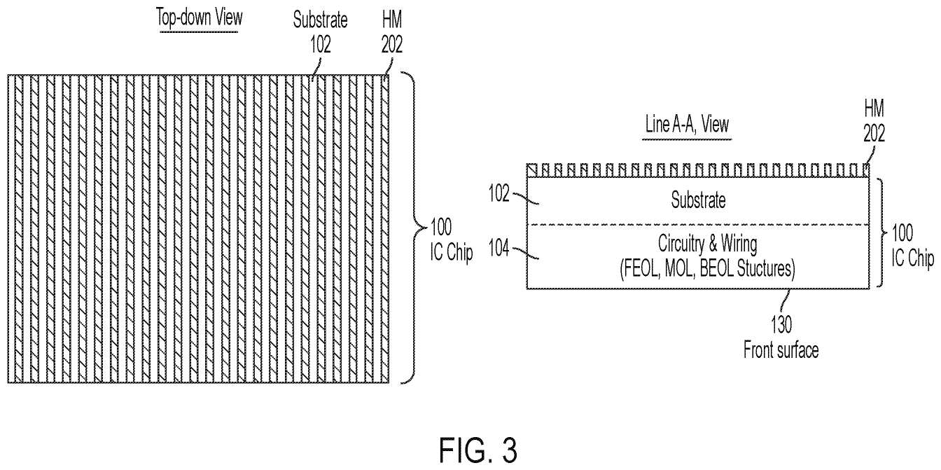

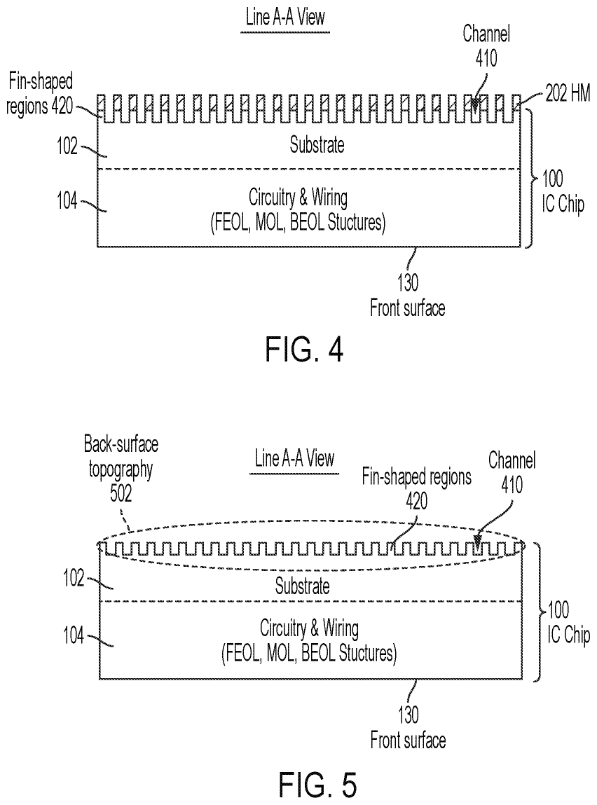

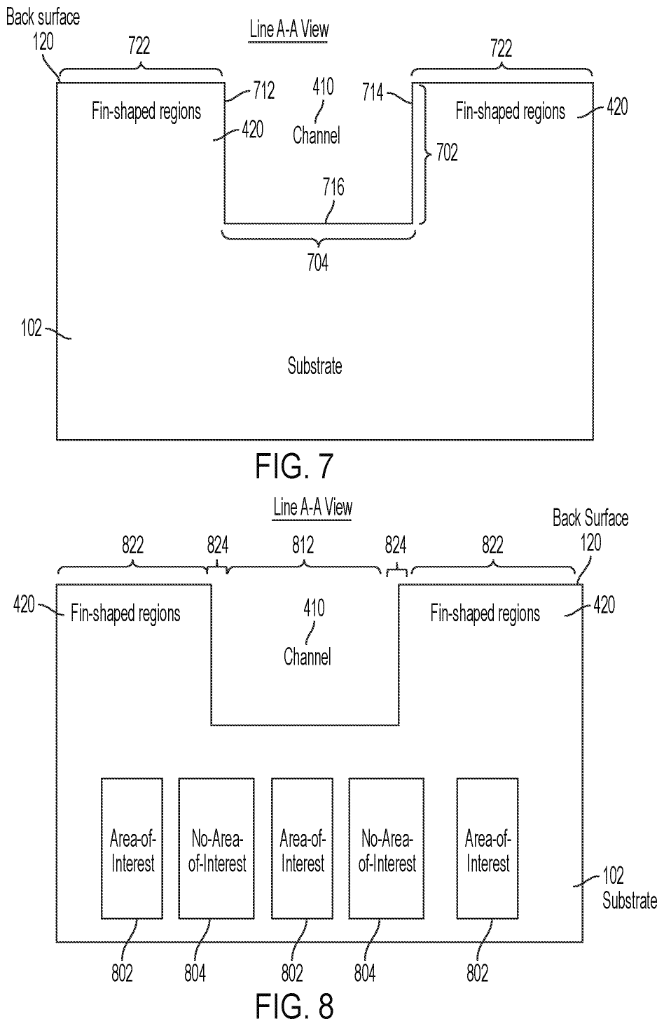

In FIG. 2 and FIG. 3, known IC fabrication operations have been used to form a hardmask 202 and position it over the back surface 120 of the substrate 102. The hardmask 202 can be any suitable dielectric material, including, for example, a silicon nitride material (e.g., Si₃Ni₄). In some embodiments, the hardmask 202 is a separate element previously patterned and positioned physically onto or in close proximity to the substrate 102 as shown in FIG. 3. In some embodiments of the invention, the hardmask 202 is first deposited on the substrate 102 as shown in FIG. 2 then patterned as shown in FIG. 3. In either approach, the hardmask 202 can, in some embodiments of the invention, be patterned using a lithography process to apply a layer of light-sensitive material known as photoresist (not shown) over the hardmask 202. Patterns (or openings) are created in the photoresist to define the location, size, and shape of channels 410 (shown in FIG. 4) and fin-shaped regions 420 (shown in FIG. 4) that define the location, size, and shape of the back-surface topography 502 (shown in FIG. 5). In some embodiments of the invention, the widths 704 (shown in FIG. 7) of the channels 410 and/or the widths 722 (shown in FIG. 7) of the fin-shaped regions 420 can be about 100 microns. In some embodiments of the invention, a laser light source (not shown) can be cast onto the photoresist to create the pattern sizes well below about 100 microns. Because the light source can directly define patterns on the photoresist that are as small as the light's wavelength, very small pattern resolutions can be achieved. In some embodiments of the invention, the lithography used to form the pattern can be an extreme ultra-violet (EUV) lithography that uses a light source with an EUV wavelength (e.g., about 13.5 nanometer wavelength) to define the photoresist pattern. In accordance with aspects of the invention, using EUV lithography to pattern the photoresist enables the formation of channels 410 and/or fin-shaped regions 420 having widths 704, 722 that can each be less than about 20 microns.

In FIG. 4, known IC etch operations (e.g., RIE) have been applied though the pattern of the hard mask 202 to form a series of the alternating channels 410 and the alternating fin-shaped regions 420, thereby forming the back-surface topography 502 (shown in FIG. 5). The IC etch operation can be a directional RIE operation that forms the channels 410 and the fin-shaped regions 420 by directionally etching through the exposed portions of the back surface 120 of the substrate 102. In accordance with aspects of the invention, the duration of the directional RIE is controlled in order to provide a desired depth 702 (shown in FIG. 7) of the channels 410.

In FIG. 5, known IC fabrication operations have been used to remove the hardmask 202, thereby exposing the channels 410 and fin-shaped region 420 that form the back-surface topography 502.

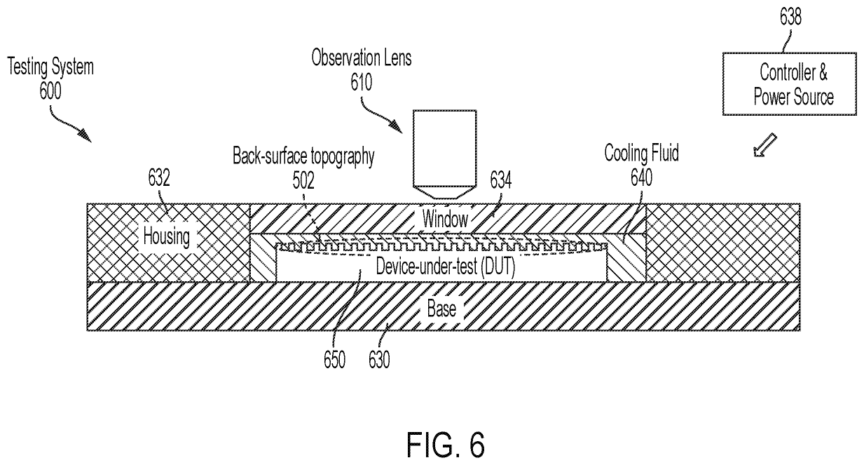

FIG. 6 depicts a simplified block diagram of a testing system 600 configured and arranged to perform testing operations on a device-under-test (DUT) 650 having a back-surface topography 502. The testing system 600 includes a base 630, a housing 632, a window 634, an observation lens 610, and a controller & power source 638, configured and arranged as shown. The DUT 650 is flipped such that its back surface is facing upward then placed within a cavity defined by the base 630, the housing 632, and the window 634 of the testing system 600. In some embodiments of the invention, the DUT 650 can be the IC chip 100. In some embodiments of the invention, the DUT 650 is the IC chip 100 assembled into a finished IC package that is physically ready for use in customer applications. The package lid and any intervening materials (e.g., thermal interface material) are removed to expose the back surface 120 of the IC chip 100, where the fabrication operations shown in FIG. 1-5 have been used (before or after packaging) to form the back-surface topography 502. During testing, the controller & power source 638 applies test pattern currents, voltages, and power levels to the DUT 650 that prompt the DUT 650 to perform operations-to-be-tested (OTBT). During testing, the cooling fluid 640 is flowed through the cavity that holds the DUT 650 to cool the DUT 650 by dissipating heat generated by the DUT 650. In embodiments of the invention where the back-surface topography 502 is implementing as alternating channels 410 (shown in FIG. 4) and fin-shaped regions 420 (shown in FIG. 4), the cooling fluid 640 is flowed in the direction of the channels 410. The DUT 650 performs the OTBT, which results in light emissions from selected portions of the DUT 650. The observation lens 610 and the controller & power source 638 are used to capture images of the light emissions through the window 634, the cooling fluid 640 and the DUT 650. The captured images can be evaluated by the controller & power source 638 to evaluate the performance of the selected portions of the DUT 650 on the OTBT.

A given OTBT (or set of OTBTs) is associated with OTBT parameters, including required power levels and heat dissipation levels (or rates). Additionally, a given OTBT is associated with an area-of-interest (AOI) and a non-area-of-interest (NAOI). For example, a set of OTBTs can require a relatively high power level (e.g., about a power density of 1 W/mm2 or more; the AOI can be a portion of the DUT 650 that includes a specific section of random access memory (RAM); and the NAOI can be all portions of the DUT 650 that do not include the specific section of RAM. Embodiments of the invention enable the performance of OTBT having high power requirements because the size, shape and depth of the back-surface topography 502 can be designed to provide surface area of the DUT 650 that is sufficient to allow enough heat dissipation to enable the required OTBT high power levels to be applied without damaging the DUT 650. Without benefit of embodiments of the present invention, the back surface of a DUT is substantially planar and cannot be adjusted, thereby setting a limit on the rate of heat dissipation through the back surface of the DUT, which sets a limit on the OTBT that can be performed by the DUT.

In some embodiments of the invention, the testing system 600 can be implemented as a picosecond imaging circuit analysis (PICA) system. PICA is based on the temporal analysis of photons emitted by CMOS ICs during transistor switching. It relies on a microchannel plate photomultiplier tube equipped with a spatial resistive anode. Using a multichannel analyzer, the detection events are allocated in a 3D array (or “PICA” image) representing the two spatial coordinates and the time with respect to a reference clock. By selecting a portion of the image, a histogram of the photon arrival time can be created and, therefore, a waveform in time of the emission activity from that location can be created. Alternatively, 2D images of the photons at specific times can be created, then a video can be constructed by combining frames. In this way, it is possible to follow the switching time of various logical ports occurring at different times inside the IC chip, thus allowing a completely non-invasive testing of circuit operation.

FIG. 7 depicts a cross-sectional line A-A view of a portion of the substrate 102 of the IC chip 100. In accordance with embodiments of the invention, the back-surface topography 502 (shown in FIG. 5) is implemented as a series of alternating fin-shaped regions 420 and channels 410. For ease of illustration, FIG. 7 depicts an expanded view of the substrate 102 showing one of the channels 410 and two of the fin-shaped regions 420. Each of the two fin-shaped regions 420 has a fin width 722. The channel 410 depicted in FIG. 7 is defined by the two fin-shaped regions 420 and a portion of a top surface of the substrate 102. More specifically, the channel 410 includes channel sidewalls 712, 714 and a bottom channel surface 716. The channel 410 further includes a channel depth 702 and a channel width 704. The channel depth 702 is determined by a duration of the etch operations depicted at FIG. 4. The channel width 704 is determined by the pattern of the hardmask 202 (shown in FIG. 3).

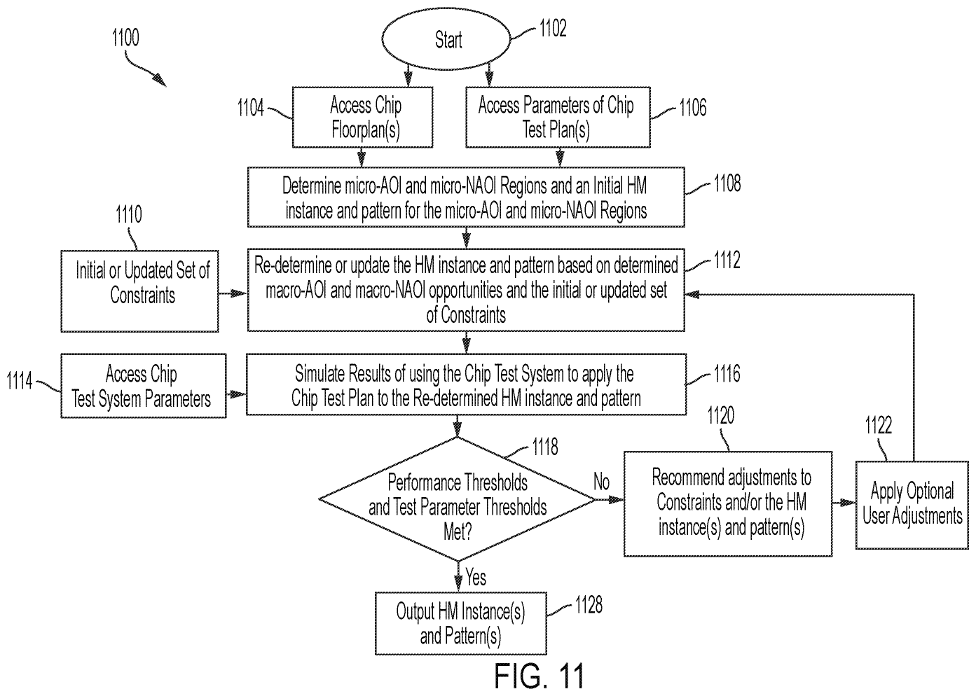

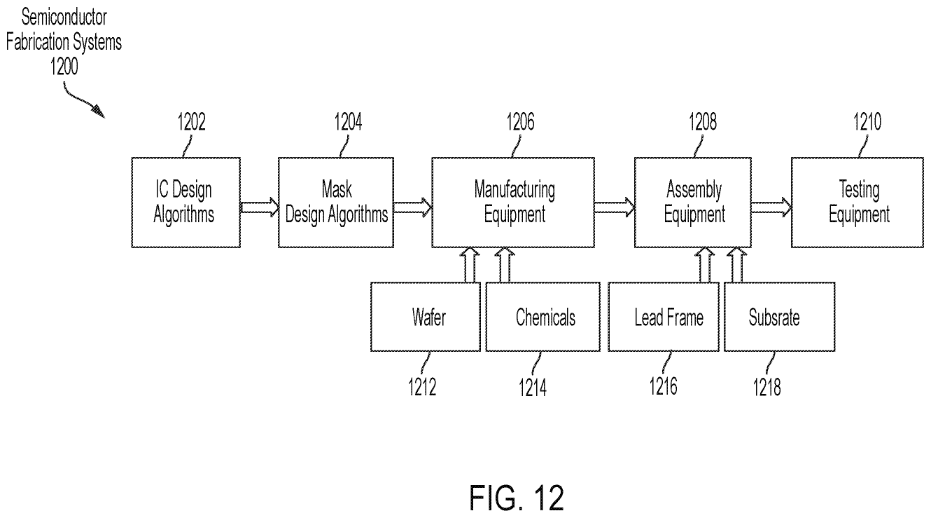

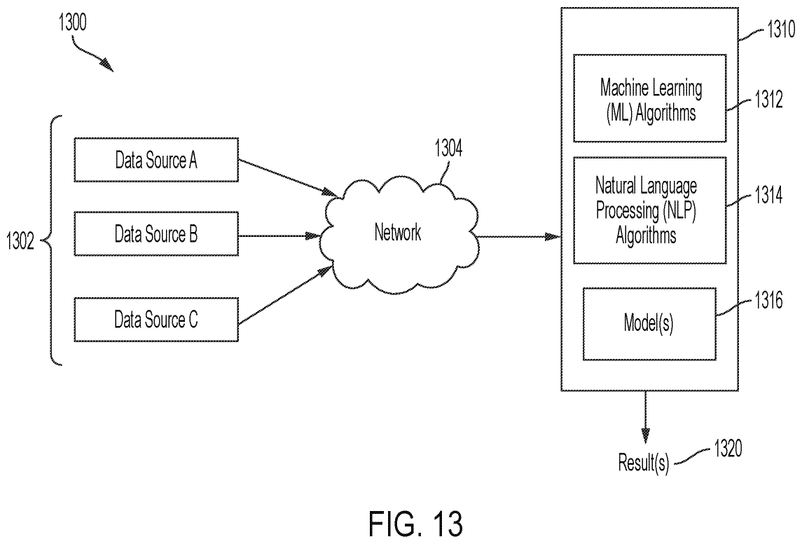

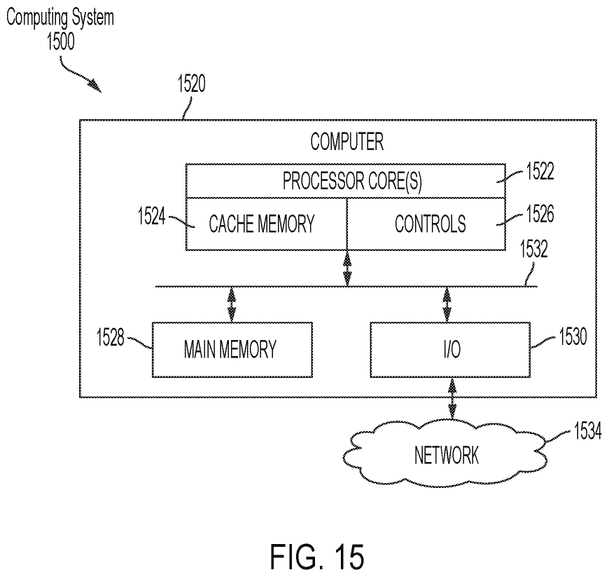

In accordance with aspects of the invention, the additional surface area provided by the alternating fin-shaped regions 420 and channels 410 in comparison with the substantially planar back surface 120 (shown in FIG. 2) is provided by the channel depth 702 of each of the channel sidewalls 712, 714. In accordance with aspects of the invention, a computing system (or processor, or processor system) 1500 (shown in FIG. 15) having computer-aided mask design tools (e.g., design algorithms 1204 shown in FIG. 12), computational fluid dynamics tools, and machine learning tools (e.g., classifier system 1300 shown in FIG. 13) is configured to perform a computer-implemented method (e.g., computer-implemented method 1100 shown in FIG. 11) that selects the channel depth 702 of each of the channel sidewalls 712, 714 to provide a surface area of the back-surface topography 502 that is sufficient to provide a level of heat dissipation level or rate required by a selected set of OTBT for a given testing system 600. Additional details of the computer-implemented method 1100 are provided below in the descriptions of FIG. 11.

Similar to FIG. 7, FIG. 8 depicts a cross-sectional line A-A view of the same portion of the substrate 102 of the IC chip 100, wherein the back-surface topography 502 (shown in FIG. 5) is implemented as a series of alternating fin-shaped regions 420 and channels 410. For ease of illustration, FIG. 8, like FIG. 7, also depicts an expanded view of the substrate 102 showing one of the channels 410 and two of the fin-shaped regions 420. FIG. 8 depicts, in accordance with aspects of the invention, results of using the above-described computing system 1500 (shown in FIG. 15) to determine placement and dimensions of the fin-shaped regions 420 and the channels 410 to improve visibility of the observation lens 610 for detecting light emissions that result from the selected OTBT.

The back-surface topography 502 can under some circumstances include regions that interfere with light emission visibility of the observation lens 610 (shown in FIG. 6) and regions that do not interfere with light emission visibility of the observation lens 610. For embodiments of the invention where the back-surface topography 502 is implemented as alternating fin-shaped regions 420 and channels 410, the regions of the back-surface topography 502 that do not interfere with the light emission visibility of the observation lens 610 are in a fin central region 822 of each fin-shaped region 420 and/or a channel central region 812 of each channel 410. Additionally, for embodiments of the invention were the back-surface topography 502 is implemented as alternating fin-shaped regions 420 and channels 410, the regions of the back-surface topography 502 that interfere with the light emission visibility of the observation lens 610 are in fin/channel edge regions 824 that are around an interface between of a fin-shaped region 420 a channel 410. In accordance with aspects of the invention, portions of the IC chip 100 that are expected to produce useful test data are identified herein as an area-of-interest (AOI), and portions of the IC chip 100 that are not expected to produce useful test data are identified herein as a non-area-of-interest (NAOI). AOI and NAOI can be determined at a micro-level or a macro-level. AOI and NAOI determined at the micro-level (i.e., at the channel/fin level) are micro-AOI 802 and micro-NAOI 804 depicted in FIG. 8. AOI and NAOI determined at the macro-level (i.e., back surface areas having unique hardmask patterns) are macro-AOI 802A, macro-AOI 802B, and macro-NAOI 804A, which are depicted in FIG. 9 and described in greater detail below.

Referring still to FIG. 8, in accordance with aspects of the invention, the computing system 1500 (shown in FIG. 15) having computer-aided mask design tools (e.g., design algorithms 1204 shown in FIG. 12), computational fluid dynamics tools, and machine learning tools (e.g., classifier system 1300 shown in FIG. 13) is configured to perform a computer-implemented method (e.g., computer-implemented method 1100 shown in FIG. 11) that improves visibility of the observation lens 610 for detecting light emissions by determining the placement and dimensions of the fin-shaped regions 420 and the channels 410 such that fin central regions 822 and channel fin regions 812 are over micro-AOI 802; and such that fin/channel edges 824 are over micro-NAOI 804. For ease of illustration, micro-AOI 802 and micro-NAOI 804 are shown in the substrate 102, but in practice micro-AOI 802 and micro-NAOI 804 extend across both the substrate 102 and the circuitry & wiring region 104. Additional details of the computer-implemented method 1100 are provided below in the descriptions of FIG. 11.

As described above, FIG. 8 depicts an example of how a single pattern of a single instance of the hardmask 202 can be designed to, in addition to improving heat dissipation, also improve visibility of the observation lens 610 (shown in FIG. 1). FIGS. 9 and 10, however, depict examples where macro-AOIs 802A, 802B and macro-NOAI 804A have been identified and separate hardmask pattern regions 1002A, 1002B, 1004A have been designed for each of the macro-AOIs 802A, 802B and the macro-NAOI 804A, respectively. In accordance with aspects of the invention, the computing system 1500 (shown in FIG. 15) having computer-aided mask design tools (e.g., design algorithms 1204 shown in FIG. 12), computational fluid dynamics tools, and machine learning tools (e.g., classifier system 1300 shown in FIG. 13) is configured to perform a computer-implemented method (e.g., computer-implemented method 1100 shown in FIG. 11) that designs the hardmask pattern region 1002A such that it, in addition to improving heat dissipation, also improves visibility of the observation lens 610 for the macro-AOI 802A; designs the hardmask pattern region 1002B such that it, in addition to improving heat dissipation, also improves visibility of the observation lens 610 for the macro-AOI 802B; and designs the hardmask pattern region 1004A such that it ignores visibility and improves (or maximizes) heat dissipation for the macro-AOI 804A without compromising performance of the DUT 650. It is understood that each of the macro-AOIs 802A, 802B will have its own set of micro-AOIs 802 (shown in FIG. 8) and micro-NAOIs 804 (shown in FIG. 8). For ease of illustration, the individual patterns used in each of the hardmask pattern regions 1002A, 1002B, 1004A are not depicted separately. Each of the hardmask pattern regions 1002A, 1002B, 1004A can be applied sequentially by blocking the portions of the back surface 120 where the hardmask pattern region (e.g., hardmask pattern region 1004A) will not be applied, applying the hardmask pattern region (e.g., hardmask pattern region 1004A) to the unblocked portion of the back surface 120, applying an etch operation through the deposited hardmask pattern region (e.g., hardmask pattern region 1004A), and removing the hardmask pattern region (e.g., hardmask pattern region 1004A).

FIG. 11 depicts the computer-implemented method 1100 in accordance with embodiments of the invention. The computer-implemented method 1100 is performed by the computing system 1500 (shown in FIG. 15) having computer-aided mask design tools (e.g., design algorithms 1204 shown in FIG. 12), computational fluid dynamics tools, and machine learning tools (e.g., classifier system 1300 shown in FIG. 13) configured to improve heat dissipation of the back-surface topography 502 (shown in FIG. 5) and visibility of the observation lens 610 for detecting light emissions by determining the placement and dimensions of hard mask patterns used to form the back-surface topography 502.

The computer-implemented method 1100 starts at block 1102 then moves to blocks 1104, 1106 to access floorplans of the DUT 650 and chip test plans (e.g., the OTBT) of the DUT 650. The floorplan identifies the location of every element of the DUT 650, and the chip test plan identifies the parameters of the tests (e.g., the OTBT) that will be performed on the DUT 650. At block 1108, the computing system 1500 uses the chip floorplans and the chip test plans to identify an initial set of the micro-AOIs 802 and the micro-NAOIs 804 for the DUT 650; determine an initial hardmask instance and pattern (e.g., hardmask 202) for the initial set of the micro-AOIs 802 and the micro-NAOIs 804; and determine an etch duration of the etchant that will be used with the hardmask pattern to form the back-surface topography 502, including specifically the channel depth 702. FIGS. 7 and 8 depict examples of the various parameters that can be determined at block 1108.

Block 1112 receives an initial or updated set of constraints from block 1110, along with the various determinations made at block 1108. At block 1112 the computing system 1500 uses these inputs to identify opportunities, if any, to segment the DUT 650 into macro-AOI regions (e.g., macro-AOIs 802A, 802B) and macro-NAOI regions (e.g., macro-NAOIs 804A); and, if appropriate, re-determine the initial hardmask instance and pattern generated at block 1108 to generate a separate hardmask instances and patterns for each macro-AOI and each macro-NAOI. The constraints provided at block 1110 can be predetermined by a user or can be recommended by the computer-implemented method 1100 (e.g., block 1120). For example, a user can set as a constraint a limit on the number of masks (e.g., no more than one mask; no more than two masks; no more than three masks; etc.) that can be determined at block 1112. As another example, a user can set as a constraint that the heat dissipation level or rate of the DUT 650 is a selected percentage above a minimum heat dissipation level or rate required by the OTBT under the chip test plans (block 1106).

Block 1116 receives from block 1114 parameters of the chip test system (e.g., testing system 600) that will be used to test the DUT 650, along with the various determinations made at block 1112. At block 116, the computing system 1500 uses these inputs to simulate results of using the chip test system (e.g., testing system 600) to the chip test plan (block 1106) to the redetermined hardmask instance and hardmask pattern (generated at block 112). The results of the simulation(s) run at block 1116 can include any aspect or parameter of the test system, the chip test plan, the hardmask instances, the hardmask patterns, and/or the DUT 650.

At decision block 1118, the computing system 1500 is used to evaluate the simulation results generated at block 116 against various thresholds, which are identified generally as performance thresholds and test parameters thresholds. For example, the performance thresholds can include thresholds that evaluate whether or not the simulated DUT 650 performs properly during testing. In some embodiments of the invention, the decision block 1118 can determine that the current channel depth(s) 702 are sufficiently large that the channel depth(s) 702 interfere with the performance of a specific element or circuit (e.g., an arithmetic logic unit (ALU)) in the DUT 650. As another example, the test parameter thresholds can include heat dissipation level and/or heat dissipation rate thresholds. In some embodiments of the invention, the decision block 1118 can determine whether or not the heat dissipation requirements for the power levels of the chip test plan applied to the simulated DUT 650 are being met.

If the results of the inquiries at decision block 1118 are yes, the computer-implemented method 1100 outputs the hardmask instance(s) and hardmask patterns generated at block 1112 and uses that output to generate hardmasks instance(s) and hardmask pattern(s) (e.g., using the design algorithms 1204 and manufacturing equipment 1206 of the semiconductor fabrication systems 1200) that are used to form the back-surface topography 502 of the DUT 650. The back-surface topography 502 and its enhanced heat dissipation capabilities, determined in accordance with embodiments of the invention, ensure that the DUT 650 will perform the selected OTBT of the chip test plan at the required power levels without overheating.

If any result of the inquiries at decision block 1118 is no, the computer-implemented method 1100 moves to block 1120 and the computing system 1500 evaluates the results generated at decision block 1118 and recommends adjustments or updates to the constraints generated at block 1110, as well as adjustments or updates to the hardmask instance(s) and/or the hardmask patterns generated at block 1112. For example, if the results generated by the decision block 1118 determines that the current channel depth(s) 702 are sufficiently large that the channel depth(s) 702 interfere with the performance of a specific element or circuit (e.g., an arithmetic logic unit (ALU)) in the DUT 650, block 1120 can recommend corrective changes to the channel widths 702. As another example, if the results generated at decision block 1118 determine that the heat dissipation requirements for the power levels of the chip test plan applied to the simulated DUT 650 are not being met, block 1120 can recommend corrective changes to the hardmask instances, hardmask patterns, and/or etch durations generated at block 1112. The computer-implemented method 1100 moves from block 1120 to block 1122 and optionally provides a user with an opportunity to make any user adjustments based on the results generated at block 1116 and decision block 1118. For example, in order to provide the computer-implemented method 1100 with additional ways to increase heat dissipation of the DUT 650, a user can manually adjust the constraint that defines a maximum number of hardmask instances. After block 1122, the computer-implemented method 1100 returns to block 1112 for a next partial iteration of the computer-implemented method 1100 that takes into account the change recommendations developed at block 1120.

FIG. 12 depicts a block diagram illustrating semiconductor fabrication systems 1200 that supports semiconductor fabrication processes capable of incorporating aspects of the invention. The semiconductor fabrication systems 1200 includes IC design support algorithms 1202, mask design support algorithms 1204, manufacturing support equipment 1206, assembly support equipment 1208, and testing support equipment 1210, configured and arranged as shown. The IC design support algorithms 1202 are configured and arranged to provide computer-aided-design (CAD) assistance with the design of the logic circuits (AND, OR, and NOR gates) that form the various logic components of the IC. Similarly, the mask design support algorithms 1204 are configured and arranged to provide CAD assistance with generating the mask design, which is the representation of an IC in terms of planar geometric shapes that correspond to the patterns of metal, oxide, or semiconductor layers that make up the components of the IC. The mask design places and connects all of the components that make up the IC such that they meet certain criteria, such as performance, size, density, and manufacturability. The manufacturing equipment 1206 is the equipment used in executing the FEOL, MOL, BEOL, and Far-BEOL processes (including singulation processes) used to form the finished wafers and IC chips (or semiconductor die). In general, the wafer manufacturing equipment 1206 come in various forms, most of which specialize in growing, depositing or removing materials from a wafer. Examples of wafer manufacturing equipment 1206 include oxidation systems, epitaxial reactors, diffusion systems, ion implantation equipment, physical vapor deposition systems, chemical vapor deposition systems, photolithography equipment, etching equipment, polishing equipment and the like. The various types of manufacturing equipment 1206 take turns in depositing and removing (e.g., using the chemicals 1214) different materials on and from the wafer 1212 in specific patterns until a circuit is completely built on the wafer 1212. The assembly equipment 1208 is used to package the IC chips into finished IC packages that are physically ready for use in customer applications. The assembly equipment 1208 can include wafer back-grind systems, wafer saw equipment, die attach machines, wire-bonders, die overcoat systems, molding equipment, hermetic sealing equipment, metal can welders, DTFS (de-flash, trim, form, and singulation) machines, branding equipment, and lead finish equipment. The major components used by the assembly equipment 1208 include but are not limited to lead frames 1216 and substrates 1218. The test equipment 1210 is used to test the IC packages so that only known good devices will be shipped to customers. Test Equipment 1210 can include automatic test equipment (ATE); test handlers; tape and reel equipment; marking equipment; burn-in ovens; retention bake ovens; UV (ultraviolet) erase equipment, and vacuum sealers.

In accordance with aspects of the invention, the computing system 1500 (shown in FIG. 15) utilizes computer-aided mask design tools (e.g., design algorithms 1204 shown in FIG. 12), computational fluid dynamics tools, and machine learning tools (e.g., classifier system 1300 shown in FIG. 13) to perform the simulation, design, parameter determinations, and recommendations of the computer-implemented method 1100. In embodiments of the invention, the various operations of the computer-implemented method 1100 can be identified as tasks, and the classifier system 1300 can be trained to perform the tasks in cooperation with other portions of the computing system 1500.

Additional details of machine learning techniques that can be used to implement aspects of the invention disclosed herein will now be provided. The various prediction and/or determination functionality of the processors described herein can be implemented using machine learning and/or natural language processing techniques. In general, machine learning techniques are run on so-called “neural networks,” which can be implemented as programmable computers configured to run sets of machine learning algorithms and/or natural language processing algorithms. Neural networks incorporate knowledge from a variety of disciplines, including neurophysiology, cognitive science/psychology, physics (statistical mechanics), control theory, computer science, artificial intelligence, statistics/mathematics, pattern recognition, computer vision, parallel processing and hardware (e.g., digital/analog/VLSI/optical).

The basic function of neural networks and their machine learning algorithms is to recognize patterns by interpreting unstructured sensor data through a kind of machine perception. Unstructured real-world data in its native form (e.g., images, sound, text, or time series data) is converted to a numerical form (e.g., a vector having magnitude and direction) that can be understood and manipulated by a computer. The machine learning algorithm performs multiple iterations of learning-based analysis on the real-world data vectors until patterns (or relationships) contained in the real-world data vectors are uncovered and learned. The learned patterns/relationships function as predictive models that can be used to perform a variety of tasks, including, for example, classification (or labeling) of real-world data and clustering of real-world data. Classification tasks often depend on the use of labeled datasets to train the neural network (i.e., the model) to recognize the correlation between labels and data. This is known as supervised learning. Examples of classification tasks include identifying objects in images (e.g., stop signs, pedestrians, lane markers, etc.), recognizing gestures in video, detecting voices, detecting voices in audio, identifying particular speakers, transcribing speech into text, and the like. Clustering tasks identify similarities between objects, which the clustering task groups according to those characteristics in common and which differentiate them from other groups of objects. These groups are known as “clusters.”

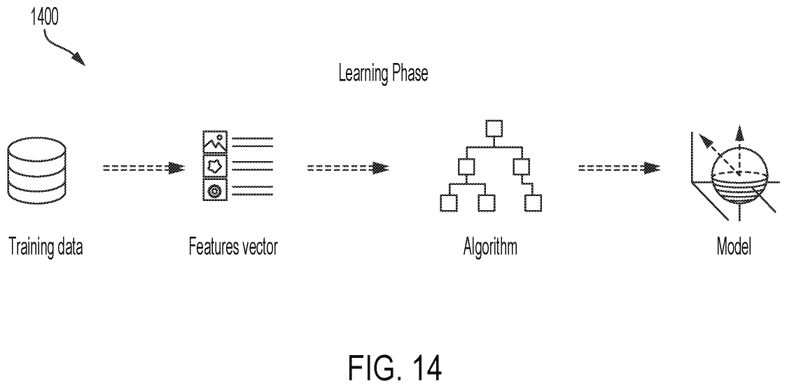

An example of machine learning techniques that can be used to implement aspects of the invention will be described with reference to FIGS. 13 and 14. FIG. 13 depicts a block diagram showing a classifier system 1300 capable of implementing various predicting and determining aspects of the invention described herein. More specifically, the functionality of the system 1300 is used in embodiments of the invention to generate various models and/or sub-models that can be used to implement predicting and determining functionality in embodiments of the invention. The classifier system 1300 includes multiple data sources 1302 in communication through a network 1304 with a classifier 1310. In some aspects of the invention, the data sources 1302 can bypass the network 1304 and feed directly into the classifier 1310. The data sources 1302 provide data/information inputs that will be evaluated by the classifier 1310 in accordance with embodiments of the invention. The data sources 1302 also provide data/information inputs that can be used by the classifier 1310 to train and/or update model(s) 1316 created by the classifier 1310. The data sources 1302 can be implemented as a wide variety of data sources, including but not limited to, sensors configured to gather real time data, data repositories (including training data repositories), and outputs from other classifiers. The network 1304 can be any type of communications network, including but not limited to local networks, wide area networks, private networks, the Internet, and the like.

The classifier 1310 can be implemented as algorithms executed by a programmable computer such as the computing system 1500 (shown in FIG. 15). As shown in FIG. 13, the classifier 1310 includes a suite of machine learning (ML) algorithms 1312; natural language processing (NLP) algorithms 1314; and model(s) 1316 that are relationship (or prediction) algorithms generated (or learned) by the ML algorithms 1312. The algorithms 1312, 1314, 1316 of the classifier 1310 are depicted separately for ease of illustration and explanation. In embodiments of the invention, the functions performed by the various algorithms 1312, 1314, 1316 of the classifier 1310 can be distributed differently than shown. For example, where the classifier 1310 is configured to perform an overall task having sub-tasks, the suite of ML algorithms 1312 can be segmented such that a portion of the ML algorithms 1312 executes each sub-task and a portion of the ML algorithms 1312 executes the overall task. Additionally, in some embodiments of the invention, the NLP algorithms 1314 can be integrated within the ML algorithms 1312.

The NLP algorithms 1314 include speech recognition functionality that allows the classifier 1310, and more specifically the ML algorithms 1312, to receive natural language data (text and audio) and apply elements of language processing, information retrieval, and machine learning to derive meaning from the natural language inputs and potentially take action based on the derived meaning. The NLP algorithms 1314 used in accordance with aspects of the invention can also include speech synthesis functionality that allows the classifier 1310 to translate the result(s) 1320 into natural language (text and audio) to communicate aspects of the result(s) 1320 as natural language communications.

The NLP and ML algorithms 1314, 1312 receive and evaluate input data (i.e., training data and data-under-analysis) from the data sources 1302. The ML algorithms 1312 include functionality that is necessary to interpret and utilize the input data's format. For example, where the data sources 1302 include image data, the ML algorithms 1312 can include visual recognition software configured to interpret image data. The ML algorithms 1312 apply machine learning techniques to received training data (e.g., data received from one or more of the data sources 1302) in order to, over time, create/train/update one or more models 1316 that model the overall task and the sub-tasks that the classifier 1310 is designed to complete.

Referring now to FIGS. 13 and 14 collectively, FIG. 14 depicts an example of a learning phase 1400 performed by the ML algorithms 1312 to generate the above-described models 1316. In the learning phase 1400, the classifier 1310 extracts features from the training data and coverts the features to vector representations that can be recognized and analyzed by the ML algorithms 1312. The features vectors are analyzed by the ML algorithm 1312 to “classify” the training data against the target model (or the model's task) and uncover relationships between and among the classified training data. Examples of suitable implementations of the ML algorithms 1312 include but are not limited to neural networks, support vector machines (SVMs), logistic regression, decision trees, hidden Markov Models (HMMs), etc. The learning or training performed by the ML algorithms 1312 can be supervised, unsupervised, or a hybrid that includes aspects of supervised and unsupervised learning. Supervised learning is when training data is already available and classified/labeled. Unsupervised learning is when training data is not classified/labeled so must be developed through iterations of the classifier 1310 and the ML algorithms 1312. Unsupervised learning can utilize additional learning/training methods including, for example, clustering, anomaly detection, neural networks, deep learning, and the like.

When the models 1316 are sufficiently trained by the ML algorithms 1312, the data sources 1302 that generate “real world” data are accessed, and the “real world” data is applied to the models 1316 to generate usable versions of the results 1320. In some embodiments of the invention, the results 1320 can be fed back to the classifier 1310 and used by the ML algorithms 1312 as additional training data for updating and/or refining the models 1316.

FIG. 15 illustrates an example of the computing system 1500 that can be used to implement any of the computer-based components of the various embodiments of the invention described herein. The computing system 1500 includes an exemplary computing device (“computer”) 1502 configured for performing various aspects of the content-based semantic monitoring operations described herein in accordance aspects of the invention. In addition to computer 1502, exemplary computing system 1500 includes network 1514, which connects computer 1502 to additional systems (not depicted) and can include one or more wide area networks (WANs) and/or local area networks (LANs) such as the Internet, intranet(s), and/or wireless communication network(s). Computer 1502 and additional system are in communication via network 1514, e.g., to communicate data between them.

Exemplary computer 1502 includes processor cores 1504, main memory (“memory”) 1510, and input/output component(s) 1512, which are in communication via bus 1503. Processor cores 1504 includes cache memory (“cache”) 1506 and controls 1508, which include branch prediction structures and associated search, hit, detect and update logic, which will be described in more detail below. Cache 1506 can include multiple cache levels (not depicted) that are on or off-chip from processor 1504. Memory 1510 can include various data stored therein, e.g., instructions, software, routines, etc., which, e.g., can be transferred to/from cache 1506 by controls 1508 for execution by processor 1504. Input/output component(s) 1512 can include one or more components that facilitate local and/or remote input/output operations to/from computer 1502, such as a display, keyboard, modem, network adapter, etc. (not depicted).

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process may include chemical mechanical polishing (CMP) or grinding. CMP is a material removal process that uses both chemical reactions and mechanical forces to remove material and planarize a surface.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and in that manner the conductors, insulators and selectively doped regions are built up to form the final device.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of preparing an integrated circuit (IC) chip for participation in test operations, the method comprising:
accessing a back surface of the IC chip; and
adding a back-surface topography to the back surface;
wherein a surface area of the back-surface topography is greater than a surface area of the back surface.

2. The method of claim 1, wherein:
accessing the back surface of the IC chip comprises exposing the back surface of the IC chip by removing a lid of an IC package that houses the IC chip;
the exposed back surface is substantially planar; and
the back-surface topography is substantially non-planar.

3. The method of claim 1, wherein adding the back-surface topography to the back surface comprises applying an etch operation through a patterned hardmask to the back surface to form the back-surface topography in the back surface.

4. The method of claim 3, wherein the back-surface topography comprises a plurality of channels formed in the back surface.

5. The method of claim 4, wherein the back-surface topography further comprise a plurality of fin-shaped regions formed in the back surface.

6. The method of claim 1, wherein adding the back-surface topography to the back surface comprises applying a first etch operation through a first hardmask to a first region of the back surface to form a first region of the back-surface topography in the back surface.

7. The method of claim 6, wherein adding the back-surface topography to the back surface further comprises applying a second etch operation through a second hardmask to a second region of the back surface to form a second region of the back-surface topography in the back surface.

8. The method of claim 7, wherein the first region of the back-surface topography is positioned under an area-of-interest for the test operations.

9. The method of claim 8, wherein the second region of the back-surface topography is positioned under a non-area-of-interest for the test operations.

10. The method of claim 9, wherein:
the first set of dimensions is configured such that a visibility through the first region of the back-surface topography of light emissions exceeds a visibility threshold; and
the second set of dimensions is configured such that a heat dissipation rate through the surface area of the back-surface topography during the test operations exceeds a heat dissipation threshold.

11. A method of testing an integrated circuit (IC) chip, the method comprising:
accessing a back surface of the IC chip;
adding a back-surface topography to the back surface;
applying a test regimen to the IC chip while applying power to the IC chip; and
flowing cooling fluid over the back-surface topography to dissipate heat generated by applying power to the IC chip;
wherein a surface area of the back-surface topography is greater than a surface area of the back surface.

12. The method of claim 11, wherein adding the back-surface topography to the back surface comprises applying an etch operation through a hardmask to the back surface to form the back-surface topography in the back surface.

13. The method of claim 12, wherein the back-surface topography comprises:
a plurality of channels formed in the back surface; and
a plurality of fin-shaped regions formed in the back surface.

14. The method of claim 11, wherein adding the back-surface topography to the back surface comprises:
applying a first etch operation through a first hardmask to a first region of the back surface to form a first region of the back-surface topography in the back surface; and
applying a second etch operation through a second hardmask to a second region of the back surface to form a second region of the back-surface topography in the back surface.

15. The method of claim 14, wherein:
the first region of the back-surface topography is positioned under an area-of-interest for the test operations; and
the second region of the back-surface topography is positioned under a non-area-of-interest for the test operations.

16. The method of claim 15, wherein:
the first set of dimensions is configured such that a visibility of light emissions through the first region of the back-surface topography exceeds a visibility threshold; and
the second set of dimensions is configured such that a heat dissipation rate through the surface area of the back-surface topography during the test operations exceeds a heat dissipation threshold.

17. An integrated circuit (IC) chip comprising:
a front surface; and
a back surface having a back-surface topography;
wherein a set of dimensions of the back-surface topography is configured to assist a heat dissipation rate through the back-surface topography during a test operation such that the heat dissipation rate exceeds a heat dissipation rate threshold.

18. The IC chip of claim 17, wherein the back-surface topography comprises a plurality of channels formed in the back surface.

19. The IC chip of claim 18, wherein the back-surface topography further comprise a plurality of fin-shaped regions formed in the back surface.

20. The IC chip of claim 17, wherein:
the set of dimensions comprise a first set of dimensions and second set of dimensions;
the first set of dimensions define a first region of the back-surface topography;
the second set of dimensions define a second region of the back-surface topography;
the first region of the back-surface topography is positioned under an area-of-interest for the test operations;
in the second region of the back-surface topography is positioned under a non-area-of-interest for the test operations; and
the first set of dimensions is configured such that a visibility level of light emissions through the first region of the back-surface topography exceeds a visibility level threshold.
